(19) United States
(12) Patent Application Publication
(10) Pub. No.: US 2016/0079176 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Atsunobu ISOBAYASHI, Yokkaichi Mie (JP); Masayuki KITAMURA, Yokkaichi Mie (JP); Yuichi YAMAZAKI, Inagi Tokyo (JP); Akihiro KAJITA, Yokkaichi Mie (JP); Tatsuro SAITO, Yokkaichi Mie (JP); Taishi ISHIKURA, Yokkaichi Mie (JP); Atsuko SAKATA, Yokkaichi Mie (JP); Tadashi SAKAI, Yokohama Kanagawa (JP); Makoto WADA, Yokkaichi Mie (JP)

(73) Assignee: KABUSHIKI KAISHA TOSHIBA, Tokyo (JP)

(21) Appl. No.: 14/656,542

(22) Filed: Mar. 12, 2015

(30) Foreign Application Priority Data
Sep. 11, 2014 (JP) 2014-185307

(51) Int. Cl. H01L 23/532; H01L 21/768; H01L 21/033

(52) U.S. Cl. CPC H01L 23/53276; H01L 21/0337; H01L 21/0331; H01L 21/76871

(57) ABSTRACT

According to one embodiment, a method of manufacturing a semiconductor device, the method includes forming a first film having a first melting point, forming a pattern of a second film on an upper surface of the first film, the second film having a second melting point lower than the first melting point, and forming a graphene film on the upper surface of the first film, the graphene film being formed from a side surface of the pattern of the second film.

### CROSS-REFERENCE TO RELATED APPLICATIONS

This application is based upon and claims the benefit of priority from Japanese Patent Application No. 2014-185307, filed Sep. 11, 2014, the entire contents of which are incorporated herein by reference.

### FIELD

Embodiments described herein relate generally to a semiconductor device.

### BACKGROUND

In connection with miniaturization of semiconductor devices, the width and height of interconnects of semiconductor integrated circuits have been reduced. Therefore, when a metal interconnect is used, the interconnect resistance is increased due to the interface inelastic scattering of electrons.

To solve the problem, use of a graphene interconnect is suggested. Normally, a graphene film used for a graphene interconnect can be formed by growing graphene from a catalytic layer.

However, it is not easy to form a graphene film of good quality in a desired region. Thus, a semiconductor device which realizes acquisition of an excellent graphene film, and its manufacturing method are desired.

### BRIEF DESCRIPTION OF THE DRAWINGS

FIG. 1 is a cross-sectional view schematically showing a part of a method for manufacturing a semiconductor device according to an embodiment.

FIG. 2 is a cross-sectional view schematically showing a part of the method for manufacturing the semiconductor device according to the embodiment.

FIG. 3 is a cross-sectional view schematically showing a part of the method for manufacturing the semiconductor device according to the embodiment.

FIG. 4 is a cross-sectional view schematically showing a part of the method for manufacturing the semiconductor device according to the embodiment.

FIG. 5 is a cross-sectional view schematically showing a part of the method for manufacturing the semiconductor device according to the embodiment.

FIG. 6 is a plan view schematically showing a chip region and a dicing region in a semiconductor substrate (semiconductor wafer) according to the embodiment.

FIG. 7 is a cross-sectional view schematically showing a part of the method for manufacturing the semiconductor device according to a first modification example of the embodiment.

FIG. 8 is a cross-sectional view schematically showing a part of the method for manufacturing the semiconductor device according to the first modification example of the embodiment.

FIG. 9 is a cross-sectional view schematically showing a part of the method for manufacturing the semiconductor device according to the first modification example of the embodiment.

FIG. 10 is a cross-sectional view schematically showing a part of the method for manufacturing the semiconductor device according to the first modification example of the embodiment.

FIG. 11 is a cross-sectional view schematically showing a part of the method for manufacturing the semiconductor device according to a second modification example of the embodiment.

FIG. 12 is a cross-sectional view schematically showing an effect of the second modification example of the embodiment.

FIG. 13 is a cross-sectional view schematically showing a part of the method for manufacturing the semiconductor device according to a third modification example of the embodiment.

### DETAILED DESCRIPTION

In general, according to one embodiment, a method of manufacturing a semiconductor device, the method includes: forming a first film having a first melting point; forming a pattern of a second film on an upper surface of the first film, the second film having a second melting point lower than the first melting point; and forming a graphene film on the upper surface of the first film, the graphene film being formed from a side surface of the pattern of the second film.

Embodiments will be described hereinafter with reference to the accompanying drawings.

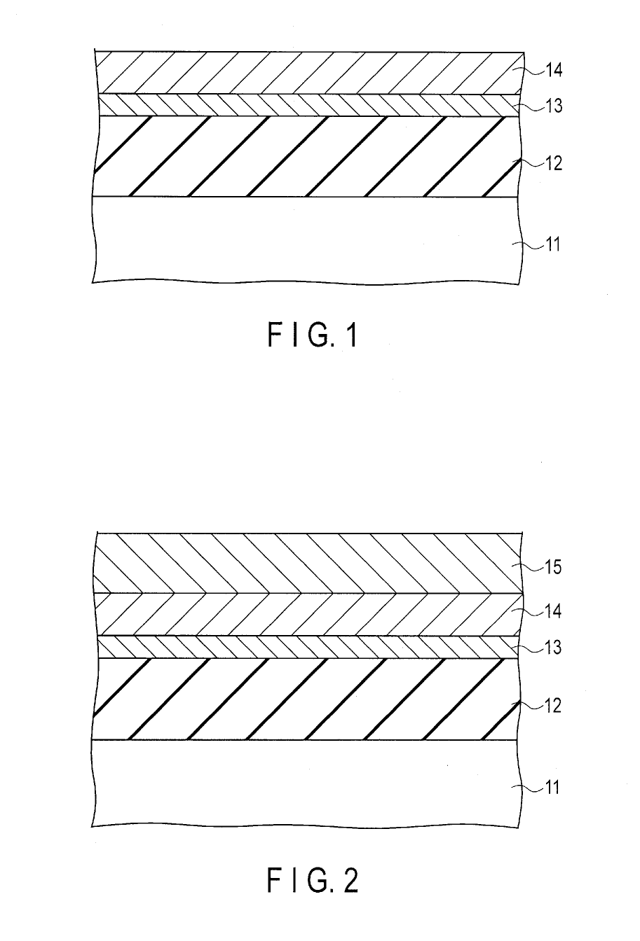

FIG. 1 to FIG. 5 are cross-sectional views schematically showing a method for manufacturing a semiconductor device according to an embodiment.

This specification explains the method for manufacturing the semiconductor device according to the embodiment with reference to FIG. 1 to FIG. 5.

Firstly, as shown in FIG. 1, an underlying insulating film 12 is formed on an underlying region 11. The underlying region 11 includes, for example, a semiconductor substrate (semiconductor wafer) and a transistor. A silicon oxide film is used for the underlying insulating film 12. Subsequently, an underlying catalytic film 13 is formed on the underlying insulating film 12. A titanium nitride film (TiN film) is used for the underlying catalytic film 13.

On the underlying catalytic film 13, a first catalytic film (first film) 14 is formed. The first catalytic film 14 functions as a catalyst for growing graphene, and has a first melting point which is relatively high.

A metal film is employed for the first catalytic film 14. The metal film used for the first catalytic film 14 is formed of a main metal element and an additional element for making the melting point of the metal film (first catalytic film 14) higher than the melting point of the main metal element. The main metal element is selected from cobalt (Co) and nickel (Ni). The additional element can be divided into two groups.

An additional element which forms a chemical compound is categorized as the first group. In this case, silicon (Si) or titanium (Ti) can be used for the additional element. Thus, the metal film used for the first catalytic film 14 is formed of Co—Si, Co—Ti, Ni—Si or Ni—Ti.

An additional element which forms a solid solution is categorized as the second group. In this case, iridium (Ir) or ruthenium (Ru) can be used for the additional element. Thus, the metal film used for the first catalytic film 14 is formed of Co—Ir, Co—Ru, Ni—Ir or Ni—Ru.

Subsequently, as shown in FIG. 2, a second catalytic film (second film) 15 is formed on the upper surface of the first catalytic film 14. The second catalytic film 15 functions as a catalyst for growing graphene, and has a second melting point which is lower than the first melting point.

A metal film is employed for the second catalytic film 15. The metal film used for the second catalytic film 15 can be divided into two cases as follows.

In the first case, the metal film used for the second catalytic film 15 is formed of a single metal element. The single metal element is selected from cobalt (Co) and nickel (Ni). Thus, the metal film used for the second catalytic film 15 is formed of Co or Ni.

In the second case, the metal film used for the second catalytic film 15 is formed of a main metal element and an additional element for making the melting point of the metal film (second catalytic film 15) lower than the melting point of the main metal element. In this case, a solid solution is formed by the additional element. The main metal element is selected from cobalt (Co) and nickel (Ni). The additional element is selected from indium (In), manganese (Mn) and copper (Cu). Thus, the metal film used for the second catalytic film 15 is formed of Co—In, Co—Mn, Co—Cu, Ni—In, Ni—Mn or Ni—Cu.

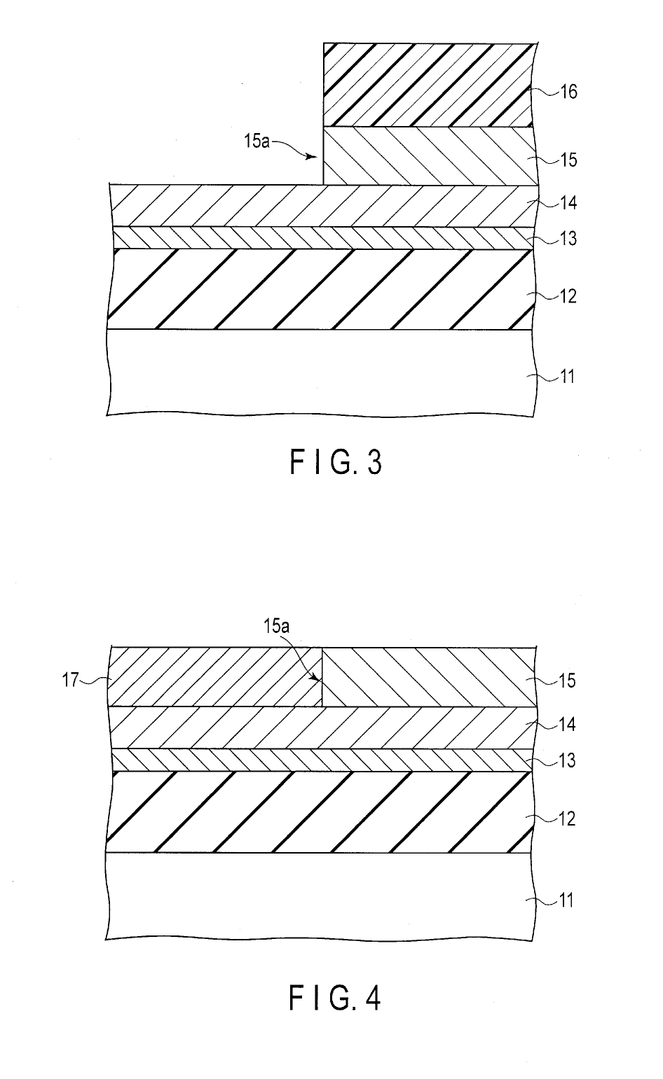

In the next step, as shown in FIG. 3, a mask pattern 16 is formed on the second catalytic film 15. A resist pattern is used for the mask pattern 16. The second catalytic film 15 is etched by using the mask pattern 16 as a mask. For this etching process, reactive ion etching (RIE) or wet etching is employed. The etching process is conducted under the condition that the etching selectivity of the second catalytic film 15 is high relative to that of the first catalytic film 14. By this etching process, the pattern of the second catalytic film 15 is formed. The pattern of the second catalytic film 15 has a side surface 15a which defines a step. Subsequently, the mask pattern 16 is removed by an ashing process.

Next, as shown in FIG. 4, a graphene film 17 is formed on the upper surface of the first catalytic film 14. The graphene film 17 is in contact with the side surface 15a of the pattern of the second catalytic film 15. The graphene film 17 is formed by a chemical vapor deposition (CVD) process at a predetermined temperature (for example, at 600° C. or below).

Now, this specification explains the graphene film 17 obtained by the step shown in FIG. 4 in detail.

In general, graphene grows from a side surface (facet) of a step. A catalytic film is employed for an underlying region having a step. However, when a catalyst having a low melting point is used, a catalytic material (catalytic metal) easily moves. Therefore, the catalytic material aggregates. As a result, a facet is formed in many places in the catalytic film. Thus, discontinuous graphene is formed. When a catalyst having a high melting point is used, a catalytic material (catalytic metal) has difficulty in moving. Therefore, the graphene growth is insufficient.

In the present embodiment, the first catalytic film 14 is formed by using a catalytic material which has a high melting point. The second catalytic film 15 is formed on the first catalytic film 14 by using a catalytic material which has a low melting point. Since the melting point of the second catalytic film 15 is low, graphene grows from the side surface (facet) 15a of the second catalytic film 15. Since the melting point of the first catalytic film 14 is high, the graphene formed on the upper surface of the first catalytic film 14 is flat. Therefore, it is possible to effectively form the graphene film 17 which has a large area and is excellent in flatness and continuousness. In addition, the graphene film 17 grows from the side surface 15a of the second catalytic film 15. The distance between the lower surface and the upper surface of the graphene film 17 corresponds to the distance between the lower edge and the upper edge of the side surface 15a of the second catalytic film 15.

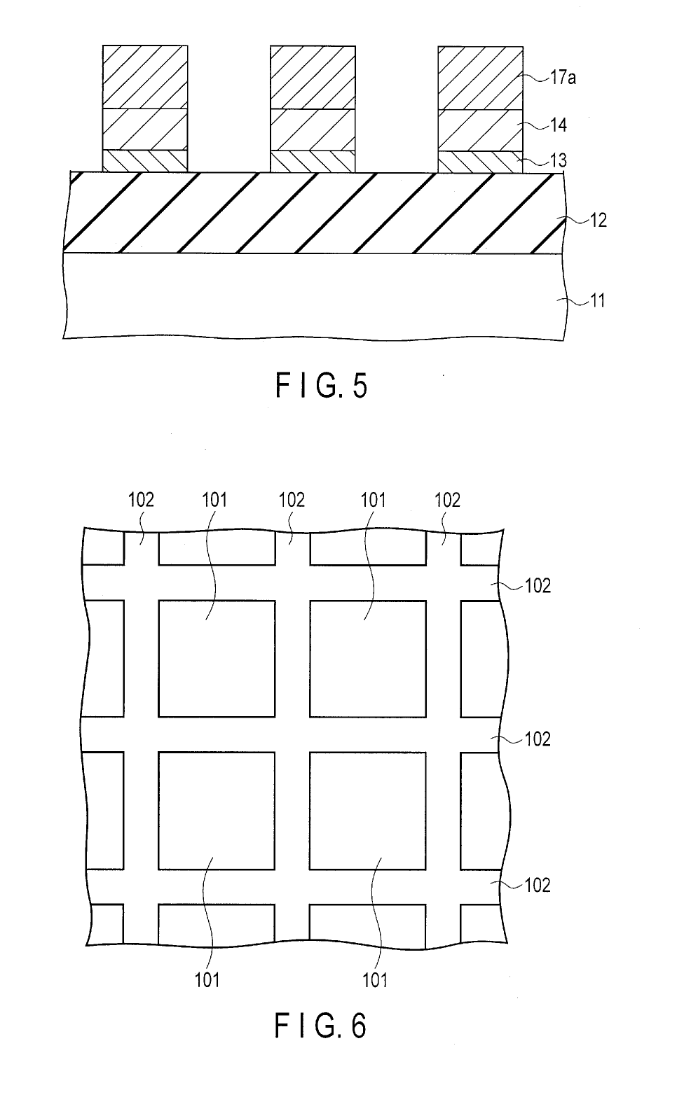

In the above manner, the graphene film 17 is formed. Subsequently, a patterning process is applied to the graphene film 17 by lithography and etching. Thus, a plurality of graphene interconnects 17a are formed as shown in FIG. 5.

As explained above, in the present embodiment, it is possible to form a graphene film which has a large area and is excellent in flatness and continuousness by forming the second catalytic film (second film) 15 having the second melting point which is lower than the first melting point on the first catalytic film (first film) 14 having the first melting point. Thus, a good interconnect having a low resistance can be obtained by using the above-mentioned graphene film to form the interconnect.

In the above embodiment, in the chip region including the graphene interconnects 17a, the second catalytic film 15 may be removed ultimately. However, in the dicing region, the structure shown in FIG. 4 remains.

FIG. 6 is a plan view schematically showing a chip region 101 and a dicing region 102 in the semiconductor substrate (semiconductor wafer). As stated above, the structure including the first catalytic film 14, the second catalytic film 15 and the graphene film 17 in FIG. 4 is formed at least in the dicing region 102.

Now, this specification explains a first modification example of the present embodiment. The basic structures are the same as the embodiment. Thus, the explanation of the structures explained in the embodiment is omitted.

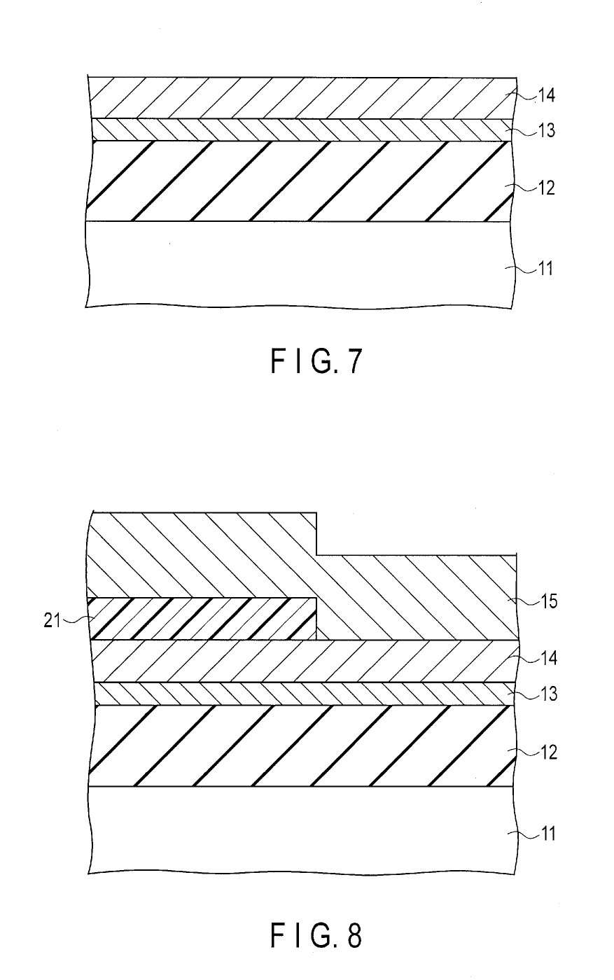

FIG. 7 to FIG. 10 are cross-sectional views schematically showing the method for manufacturing the semiconductor device according to the first modification example.

Firstly, as shown in FIG. 7, in the same manner as the embodiment, the underlying insulating film 12, the underlying catalytic film 13 and the first catalytic film (first film) 14 are formed on the underlying region 11.

Subsequently, as shown in FIG. 8, a resist pattern is formed as a liftoff pattern 21 on the first catalytic film 14. After the formation, the second catalytic film (second film) 15 is formed on the first catalytic film 14 and the liftoff pattern 21.

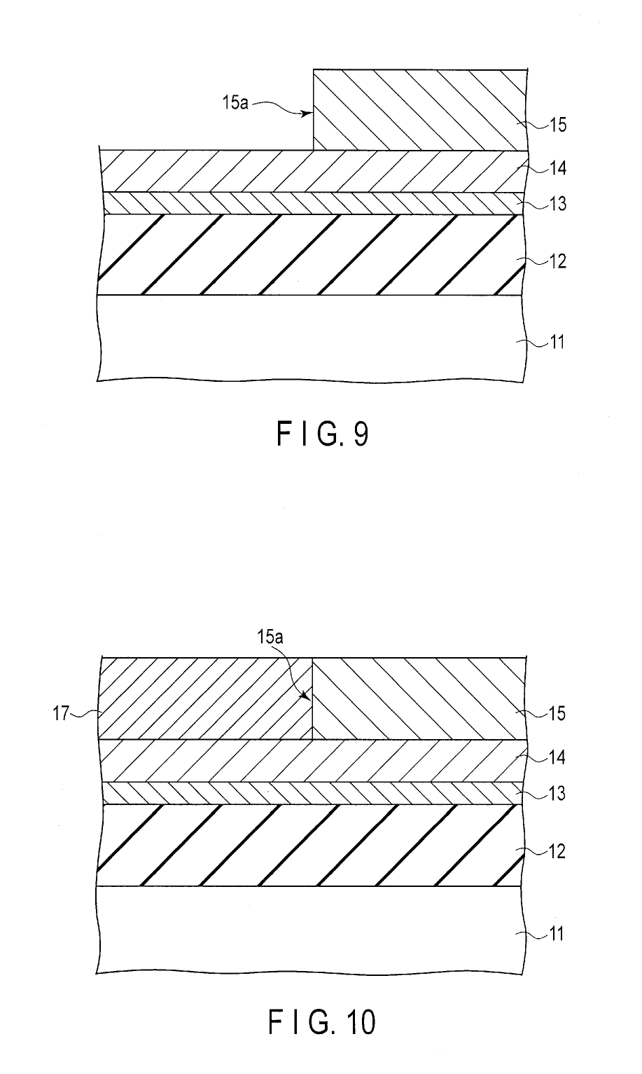

In the next step, as shown in FIG. 9, the second catalytic film 15 on the liftoff pattern 21 is eliminated by a liftoff process. Specifically, the liftoff pattern 21 and the second catalytic film 15 on the liftoff pattern 21 are removed by a wet process using thinner. In this manner, the pattern of the second catalytic film 15 is formed. The pattern of the second catalytic film 15 has the side surface 15a which defines a step.

Subsequently, as shown in FIG. 10, in the same manner as the above embodiment, the graphene film 17 is formed on the upper surface of the first catalytic film 14. The graphene film 17 is in contact with the side surface 15a of the pattern of the second catalytic film 15. In this modification example, in the same manner as the embodiment, graphene grows from the side surface (facet) 15a of the second catalytic film 15.

In the above manner, the graphene film 17 is formed. After the formation, a patterning process is applied to the graphene film 17 in the same manner as the embodiment. Thus, the plurality of graphene interconnects 17a are formed in the same manner as FIG. 5 of the embodiment.

In this modification example, in the same manner as the embodiment, it is possible to form a graphene film which has a large area and is excellent in flatness and continuousness by forming the second catalytic film (second film) 15 having the second melting point which is lower than the first melting point on the first catalytic film (first film) 14 having the first melting point. Thus, a good interconnect having a low resistance can be obtained by using the aforementioned graphene film to form the interconnect.

In this modification example, the second catalytic film 15 on the liftoff pattern 21 is removed by the liftoff process. Thus, the upper surface of the first catalytic film 14 is little-etched, and maintains a surface state which is excellent in flatness. By forming a graphene film on the surface which is excellent in flatness, a graphene film of good quality can be obtained.

Now, this specification explains a second modification example of the embodiment. The basic structures are the same as the embodiment. Thus, the explanation of the structures explained in the embodiment is omitted.

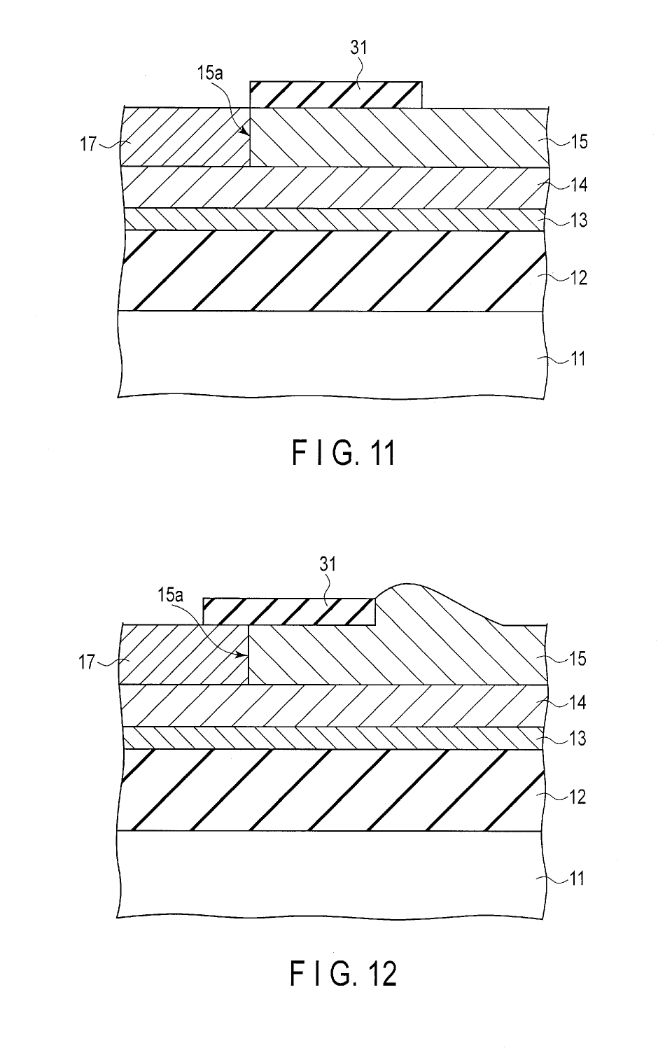

FIG. 11 is a cross-sectional view schematically showing a part of the method for manufacturing the semiconductor device according to the second modification example.

In this modification example, an aggregation inhibiting film 31 is formed on the pattern of the second catalytic film 15 before the graphene film 17 is formed in the step of FIG. 4 of the above embodiment. The aggregation inhibiting film 31 inhibits aggregation of the second catalytic film 15. The aggregation inhibiting film 31 is provided on a predetermined part of the pattern of the second catalytic film 15. The predetermined part includes a neighboring region of the side surface 15a of the pattern of the second catalytic film 15. For example, a silicon oxide film or a silicon nitride film can be used for the aggregation inhibiting film 31.

As stated above, the second catalytic film 15 has a low melting point, and easily moves. Therefore, when the graphene film 17 is formed, the second catalytic film 15 may deform in the neighboring region of the side surface 15a of the second catalytic film 15. In this modification example, the aggregation inhibiting film 31 is provided to restrict the move of the second catalytic film 15. In other words, the aggregation of the second catalytic film 15 is restricted. In this modification example, it is possible to prevent the second catalytic film 15 from deforming in the neighboring region of the side surface 15a. From a different point of view, the graphene film 17 can be surely grown from the side surface 15a of the second catalytic film 15.

The aggregation inhibiting film 31 is selectively provided on the predetermined part of the second catalytic film 15. The predetermined part includes the neighboring region of the side surface 15a of the pattern of the second catalytic film 15. Therefore, the region in which the aggregation inhibiting film 31 is not formed is a free surface. In this region, the move of the second catalytic film 15 is not restricted. Thus, as shown in FIG. 12, the second catalytic film 15 can be deformed in the region in which the aggregation inhibiting film 31 is not formed when the second catalytic film 15 goes back. In other words, the region in which the aggregation inhibiting film 31 is not formed can function as a sink region of the second catalytic film 15.

As described above, in this modification example, the aggregation inhibiting film 31 is provided to prevent the second catalytic film 15 from deforming in the neighboring region of the side surface 15a of the second catalytic film 15. Thus, it is possible to form an excellent graphene film.

Now, this specification explains a third modification example of the embodiment. The basic structures are the same as the embodiment. Thus, the explanation of the structures explained in the embodiment is omitted.

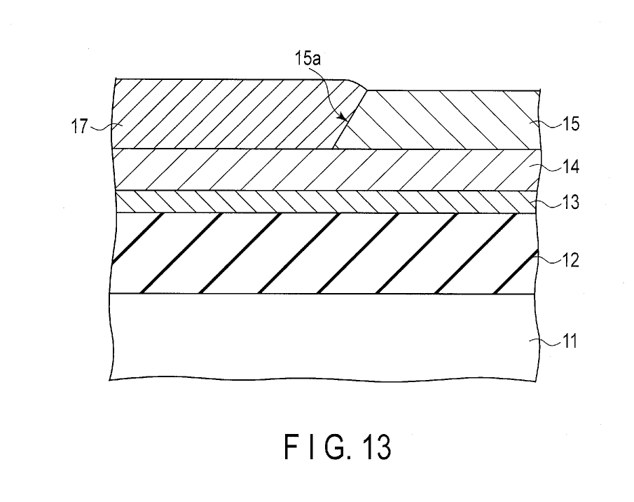

FIG. 13 is a cross-sectional view schematically showing a part of the method for manufacturing the semiconductor device according to the third modification example.

In the above-described embodiment, the side surface 15a of the second catalytic film 15 is perpendicular. In this modification example, the side surface 15a of the second catalytic film 15 is inclined. In this manner, the side surface 15a of the second catalytic film 15 may be inclined. A graphene film 17 may be grown from the inclined surface.

Even when the side surface 15a of the second catalytic film 15 is inclined, the graphene film 17 grows from the side surface 15a. Thus, the distance between the lower surface and the upper surface of the graphene film 17 corresponds to the distance between the lower edge and the upper edge of the side surface 15a of the second catalytic film 15.

In the above embodiment, the first catalytic film 14 is used for the first film. This means that the first film functions as a catalyst at the time of graphene growth. However, the first film does not necessarily have to function as a catalyst. For example, tungsten (W) or a titanium nitride (TiN) may be used for the first film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming a first film having a first melting point;
forming a pattern of a second film on an upper surface of the first film, the second film having a second melting point lower than the first melting point; and
forming a graphene film on the upper surface of the first film, the graphene film being formed from a side surface of the pattern of the second film.

2. The method of claim 1, wherein
forming the pattern of the second film comprises:
forming the second film on the first film;
forming a mask pattern on the second film; and
etching the second film using the mask pattern as a mask.

3. The method of claim 1, wherein
forming the pattern of the second film comprises:
forming a liftoff pattern on the first film;
forming the second film on the first film and the liftoff pattern; and
removing the second film on the liftoff pattern by a liftoff process.

4. The method of claim 1, wherein
an aggregation inhibiting film inhibiting aggregation of the second film is provided on the pattern of the second film before the graphene film is formed.

5. The method of claim 4, wherein
the aggregation inhibiting film is provided on a predetermined part of the pattern of the second film, the predetermined part including a neighboring region of the side surface of the pattern of the second film.

6. The method of claim 1, wherein
the second film functions as a catalyst for growing graphene.

7. A semiconductor device comprising:
a first film having a first melting point;
a second film provided on an upper surface of the first film, the second film having a second melting point lower than the first melting point; and
a graphene film provided on the upper surface of the first film, the graphene film being in contact with a side surface of the second film.

8. The device of claim 7, wherein
the second film is a metal film.

9. The device of claim 8, wherein
the metal film is formed of a single metal element.

10. The device of claim 9, wherein
the single metal element is selected from cobalt (Co) and nickel (Ni).

11. The device of claim 8, wherein
the metal film is formed of a main metal element and an additional element for making a melting point of the metal film lower than a melting point of the main metal element.

12. The device of claim 11, wherein
the main metal element is selected from cobalt (Co) and nickel (Ni), and
the additional element is selected from indium (In), manganese (Mn) and copper (Cu).

13. The device of claim 7, wherein
the second film functions as a catalyst for growing graphene.

14. The device of claim 7, wherein
the first film is a metal film.

15. The device of claim 14, wherein
the metal film is formed of a main metal element and an additional element for making a melting point of the metal film higher than a melting point of the main metal element.

16. The device of claim 15, wherein
the main metal element is selected from cobalt (Co) and nickel (Ni), and
the additional element is selected from silicon (Si), titanium (Ti), iridium (Ir) and ruthenium (Ru).

17. The device of claim 7, further comprising
an aggregation inhibiting film provided on the second film, the aggregation inhibiting film inhibiting aggregation of the second film.

18. The device of claim 17, wherein
the aggregation inhibiting film is provided on a predetermined part of the second film, the predetermined part including a neighboring region of the side surface of the second film.

19. The device of claim 7, wherein
a distance between a lower surface and an upper surface of the graphene film corresponds to a distance between a lower edge and an upper edge of the side surface of the second film.

20. The device of claim 7, wherein
the first film, the second film and the graphene film are provided in a dicing region.
